(19) United States
(12) Patent Application Publication
(10) Pub. No.: US 2007/0152332 A1
(43) Pub. Date: Jul. 5, 2007

(54) SINGLE OR DUAL DAMASCENE VIA LEVEL WIRINGS AND/OR DEVICES, AND METHODS OF FABRICATING SAME

(75) Inventors: Anil K. Chinthakindi, Poughkeepsie, NY (US); Douglas D. Coolbaugh, Highland, NY (US); Ebenezer E. Eshun, Newburgh, NY (US); Vincent J. McGahay, Poughkeepsie, NY (US); Anthony K. Stamper, Williston, VT (US); Kunal Vaed, Poughkeepsie, NY (US); Richard P. Volant, New Fairfield, CT (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/306,596

(22) Filed: Jan. 4, 2006

(51) Int. Cl. H01L 21/44

(52) U.S. Cl. 257/750; 438/652

(57) ABSTRACT

The present invention relates to integrated circuits that comprise via-level wirings and/or devices. Specifically, an integrate circuit of the present invention comprises a first line level and a second line level spaced apart from each other, with a via level therebetween. The first and second line levels both comprise metal wirings and/or electronic devices. The via level comprises at least one metal via that extends therethrough to electrically connect the first line level with the second line level. Further, the via level comprises at least one via-level metal wiring and/or electronic device.

### FIELD OF THE INVENTION

The present invention generally relates to integrated circuits (ICs) that comprise sub-level wirings and/or devices, and methods for fabricating same. More specifically, the present invention relates to ICs that comprise wirings and/or devices that are located in at least one via level between two adjacent line levels.

### BACKGROUND OF THE INVENTION

Integrated circuit (IC) designs typically comprise multiple levels of wirings and/or devices that are isolated from one another by an inter-level dielectric (ILD) and are interconnected by multiple metal vias therebetween. The levels at which the wirings and/or devices are located are typically referred to as the “line levels,” while the levels at which the metal vias are located are typically referred to as the “via levels.”

As IC chips are aggressively scaled, the density of wiring and/or devices at the line levels increases significantly and gradually reaches the maximum density allowed for optimal device performance.

There is a continuing need for further reducing the sizes of the IC chips without adversely affecting the device performance.

### SUMMARY OF THE INVENTION

The present invention, in one aspect relates to an integrate circuit (IC) device, which comprises:
a first line level comprising metal wirings, electronic devices, or a combination of both;
a second line level spaced apart from the first line level, wherein the second line level comprises metal wirings, electronic devices, or a combination of both; and
a via level between the first and second line levels, wherein the via level comprises at least one metal via that extends therethrough to electrically connect the first line level with the second line level, and wherein the via level further comprises metal wirings, electronic devices, or a combination of both.

The present invention, in another aspect, relates to an on-chip capacitor comprising:
a first line level comprising metal wirings having a wire width ranging from about 3 μm to about 5 μm;
a second line level spaced apart from the first line level, wherein the second line level comprises metal wirings having a wire width ranging from about 0.3 μm to about 0.5 μm; and
a via level between the first and second line levels, wherein the via level comprises metal wirings having a wire width ranging from about 0.3 μm to about 0.5 μm.

A further aspect of the present invention relates to a method for forming an IC device, comprising:
forming a lower line level in a first inter-level dielectric (ILD) layer, wherein the lower line level comprises metal wirings, electronic devices, or a combination of both;
depositing a second inter-level ILD layer over the first ILD layer;
forming metal wirings, electronic devices, or a combination of both in the second inter-level ILD layer;
depositing a third inter-level ILD layer over the second ILD layer;
forming an upper line level in the third ILD layer, wherein the upper line level comprises metal wirings, electronic devices, or a combination of both,
wherein the second ILD layer defines a via level with metal wirings, electronic devices, or a combination of both located therein, and wherein at least one metal via extends through the via level for electrically connecting the upper and lower line levels.

Other aspects, features and advantages of the invention will be more fully apparent from the ensuing disclosure and appended claims.

### BRIEF DESCRIPTION OF THE DRAWINGS

FIG. 1 shows a partial cross-sectional view of a conventional IC chip containing metal wirings that are located at two isolated line levels and are connected with each other by metal vias located at an intermediate via level.

FIG. 2A shows a partial cross-sectional view of an IC chip containing metal wirings that are adjacent to metal vias at an intermediate via level between two isolated line levels, according to one embodiment of the present invention.

FIG. 2B shows a partial cross-sectional view of an IC chip containing metal wirings that are adjacent to metal vias at an intermediate via level between two isolated line levels, wherein the IC chip comprises hybrid ILD composed of two different dielectric materials, according to one embodiment of the present invention.

FIGS. 3A-3E are partial cross-sectional views that illustrate exemplary dual damascene processing steps for forming an IC chip containing via level wirings, according to one embodiment of the present invention.

FIG. 4A-4C are partial cross-sectional views that illustrate exemplary single damascene processing steps for forming an IC chip containing via level wirings, according to one embodiment of the present invention.

FIG. 5 is a top view of an IC chip containing capacitors located in a via level under a line level that contains wide metal wirings for the power, ground, and signal lines, according to one embodiment of the present invention.

FIGS. 6A and 6B are the top and partial cross-sectional views of a prior art on-chip capacitor.

FIGS. 7A and 7B are the top and partial cross-sectional views of an on-chip capacitor formed by a single damascene process with via level metal wirings, according to one embodiment of the present invention.

FIGS. 8A and 8B are the top and partial cross-sectional views of an on-chip capacitor formed by a dual damascene process with via level metal wirings, according to one embodiment of the present invention.

### DETAILED DESCRIPTION OF THE INVENTION

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

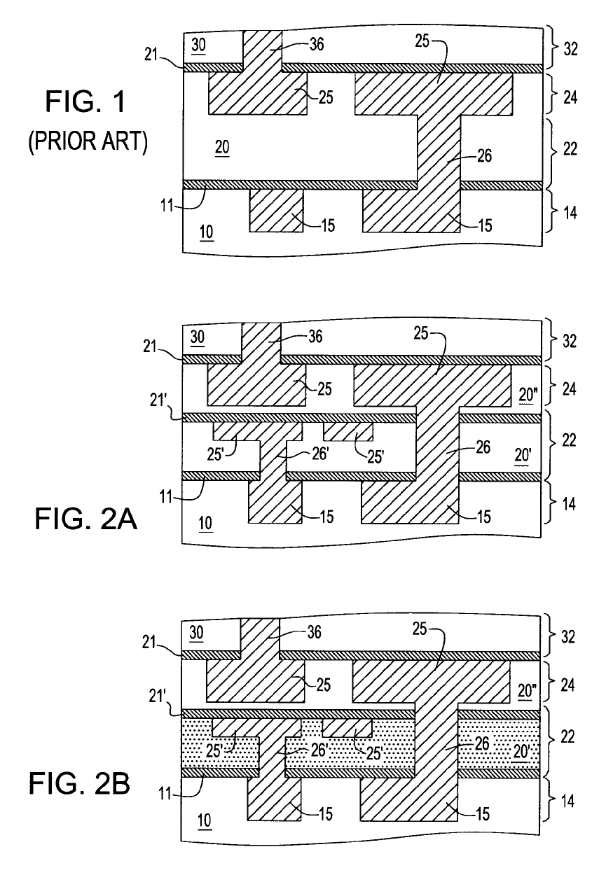

It has been observed by the inventors that the line levels of currently available IC chip designs are often populated by densely arranged wirings and/or devices, while the via levels contain only sparsely dispersed metal vias. For instance, FIG. 1 shows a partial cross-sectional view of a conventional IC chip containing inter-level dielectric (ILD) layers 10, 20, and 30 with capping layers 11 and 21 therebetween. Metal wirings 15 are located at a lower line level 14 in the ILD layer 10. Metal wirings 25 are located at an upper line level 24 in the ILD layer 20. Metal wirings 15 are electrically connected to the metal wirings 25 by a metal via 26 located at an intermediate via level 22. Further, metal wirings 15 are electrically connected to other metal wirings (not shown) by a metal via 36 located in an upper via level 32.

The line levels 14 and 24 are densely populated with metal wirings 15 and 25 as well as microelectronic devices (not shown). In contrast, the via levels 22 and 32 contain only sparsely placed metal vias 26 and 36 surrounded by empty spaces. The relatively empty via levels in conventional IC chips therefore constitute underutilized “real estate.”

In order to further reduce the size of IC chips without adversely affecting the device performance, the present invention proposes improved IC chip designs that fully utilize the via level “real estate” or space, by populating the via levels of the IC chips with metal wirings and/or devices. Specifically, metal wirings and/or devices of relatively small sizes can be relocated from the line levels to the via levels of the IC chips. In this manner, the density of wirings and/or devices at the line levels can be significantly reduced, thereby allowing further scaling of the IC chips without adversely affecting the device performance.

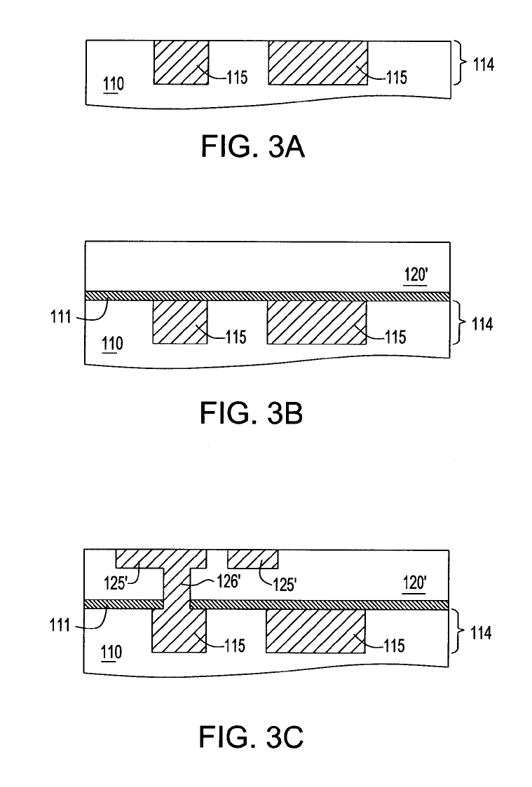

FIGS. 2A and 2B show partial cross-sectional views of two exemplary IC chips of slightly different configurations, according to two specific embodiments of the present invention. A new capping layer 21′ is provided to divide the ILD layer 20 contained by the conventional IC chip shown in FIG. 1 into a via-level ILD layer 20′ located at the via level 22 and a line-level ILD layer 20″ located at the line level 24. The metal via 26 extends through the via-level ILD layer 20′ and the new capping layer 21′ to connect the metal wirings 15 at the lower line level 14 and the metal wirings 25 at the upper line level 24. Within the via-level ILD layer 20′, metal wirings 25′ of reduced sizes are provided, which are connected to the metal wirings 15 at the lower line level 14 via metal vias 26′ of reduced sizes.

The via-level ILD layer 20′ and the line-level ILD layer 20″ may comprise the same dielectric material, as shown in FIG. 2A.

Alternatively, layers 20′ and 20″ may comprise two different dielectric materials to form a hybrid ILD structure, as shown in FIG. 2B. Preferably, but not necessarily, the via-level ILD layer 20′ comprises a low-k dielectric material having a low coefficient of thermal expansion (CTE) (e.g., less than about 30 ppm/° C.), such as SiCOH (e.g., a silicon doped oxide) or an oxide dielectric material, for the purpose of increasing reliability, while the line-level ILD layer 20″ comprises a low-k polymeric thermoset dielectric material, such as SiLK™ (an aromatic hydrocarbon thermosetting polymeric dielectric material available from the Dow Chemical Company, which has a dielectric constant of about 2.65). For more details regarding the hybrid ILD structures, see U.S. Patent Application Publication No. 2005/0023693, as published on Feb. 3, 2005, the content of which is incorporated herein by reference in its entirety for all purposes.

The present invention therefore provides an improved IC design that contains via-level wirings and/or devices (not shown). Such an IC design fully utilizes the underutilized space in the via levels of conventional IC chips, and allows further size reduction of the IC chips without adversely impacting the device performance.

Note that in FIGS. 2A and 2B, which are not drawn to scale, only one via is shown at each via level, and only two metal wirings are shown at each line level. Although illustration is made to such an embodiment, the present invention is not limited to any specific number of vias or wirings at any specific via level or line level.

Further, other logic circuitry components, which include, but are not limited to: capacitors, diodes, resistors, transistors, inductors, varactors, etc., can be readily incorporated into the via levels and/or line levels of the IC chips of the present invention. For example, any of the line/via levels 14, 22, 24, and 32 may contain one or more capacitors, diodes, resistors, transistors, inductors, or varactors.

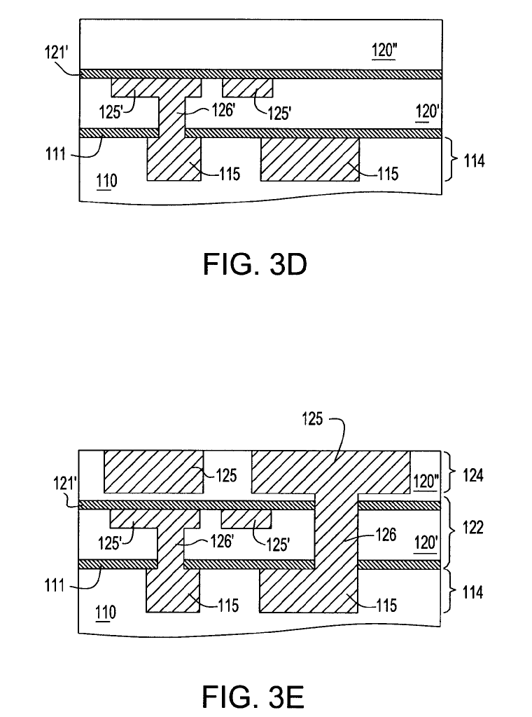

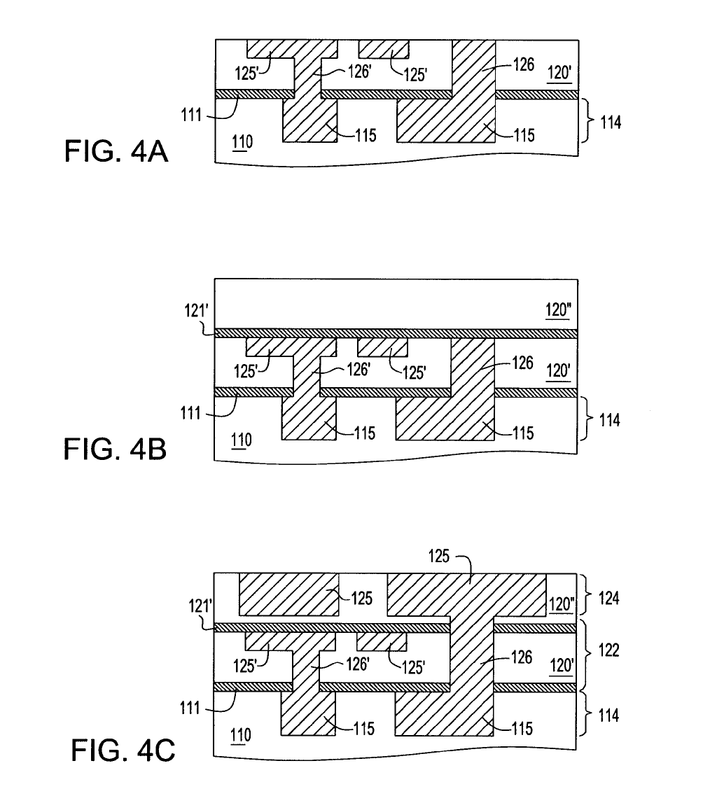

The exemplary processing steps for forming the IC chips of the present invention will now be described in greater detail by referring to the accompanying FIGS. 3A-4C.

Specifically, FIGS. 3A-3E illustrate exemplary dual damascene processing steps for forming an IC chip according to one embodiment of the present invention.

Reference is first made to FIG. 3A, which shows formation of metal wirings 115 in a first ILD layer 110, thereby forming a first line level 114. FIG. 3B shows deposition of a capping layer 111 over the first ILD layer 110, followed by deposition of a via-level ILD layer 120′. Metal wirings 125′ and metal via 126′ are then formed in the via-level ILD layer 120′ by a dual damascene process. Specifically, the metal wirings 125′ are electrically connected to the metal wirings 115 at the first line level 114 by the metal vias 126′, as shown in FIG. 3C.

Next, another capping layer 121′ is deposited over the via-level ILD layer 120′, followed by deposition of a line-level ILD layer 120″, as shown in FIG. 3D. Another dual damascene process is then carried out to form metal wirings 125 as well as metal via 126. The metal wirings 125 are located at a second line level 124 in the line-level ILD layer 120″. The metal via 126, on the other hand, is located at a via level 122 in the via-level ILD layer 120′, and it extends through the via-level ILD layer 120′ to electrically connect the metal wirings 125 at the second line level 124 with the metal wirings 115 at the first line level 114, as shown in FIG. 3E.

Alternatively, the IC chip of the present invention can be readily formed by single damascene processing steps. For example, FIGS. 4A-4C illustrate exemplary single damascene processing steps for forming the IC chip of the present invention. The metal vias 126′ and 126 are first formed in the via-level ILD layer 120′ by a first single damascene step, and the metal wirings 125′ are then formed by a second single damascene step, as shown in FIG. 4A. The capping layer 121′ and the line-level ILD layer 120″ are subsequently deposited over the previously formed metal vias 126′, 126, and metal wirings 125′, followed by formation of the metal wirings 125 via a third single damascene step, as shown in FIGS. 4B and 4C.

The IC chip so formed contains via-level metal wirings 125′ at the via level 122, as shown in FIGS. 3E and 4C. Further, such an IC chip may contain additional via-level electronic devices or logic circuitry components (not shown), such as capacitors, diodes, resistors, transistors, inductors, etc., at the via level 122, and it may also additional line-level devices or components at the line level(s) 114 and/or 124.

In a particularly preferred embodiment of the present invention, the IC chip contains via-level capacitor(s). More preferably, the via-level capacitor(s) are located at a via level under a line level that contains power lines, ground lines, and/or signal lines that typically require relatively wide metal wirings.

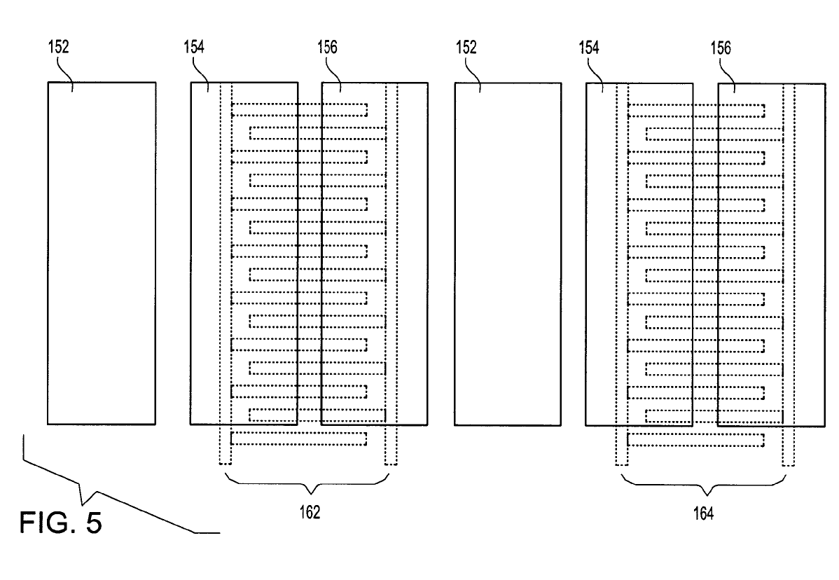

For example, FIG. 5 shows a top view of an IC chip, which contains wide signal lines 152, power lines 154, and ground lines 156 (shown by the solid lines) located at the same line level. Reduced pitch capacitors 162 and 164 (shown by the dotted lines) are provided in a via level that is directly under the line level at which lines 152, 154, and 156 are located. Therefore, the typically un-utilized spaces in the via level under the wide signal/power/ground lines 152, 154, and 156 are now occupied by the via-level capacitors 162 and 164, which help to increase the device capacitance without adversely affecting the signal speed.

Further, since capacitors do not carry steady currents, they can be formed by alternative metallization (such as aluminum, tungsten, and platinum), so as to reduce the costs and complexity typically associated with standard copper damascene.

Conventional on-chip capacitors typically comprise multiple levels of metal wirings that are interconnected with each other by metal vias. The metal wirings at each level form a comb-shaped capacitive structure that contains a positive terminal and a negative terminal with alternating positive and negative electrodes therebetween. Each level of metal wirings defines a line level, and each level of metal vias defines a via level.

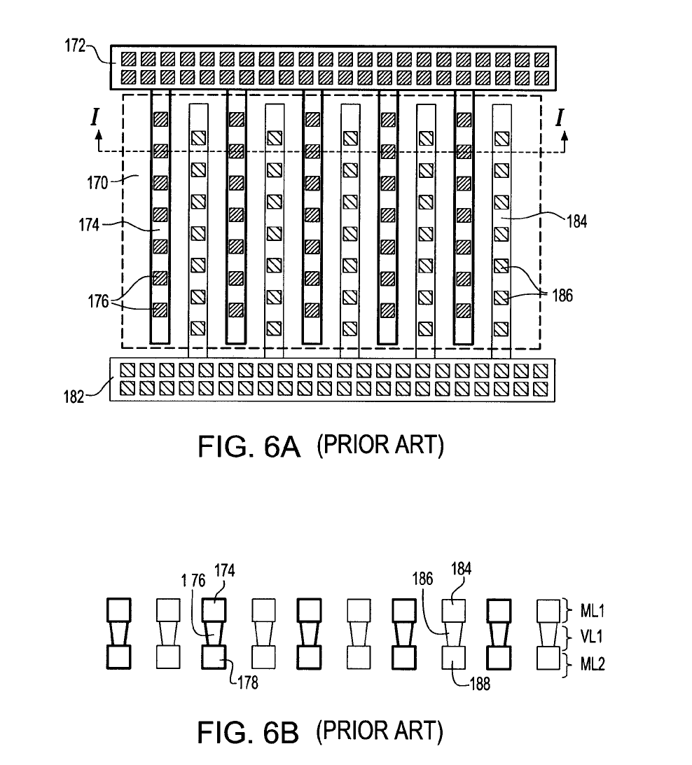

For example, FIG. 6A shows a top view of a conventional on-chip capacitor, which contains at least one capacitive structure formed by metal wirings located at a specific line level. Such a capacitive structure preferably comprises a positive terminal 172 and a negative terminal 182, which defines a capacitive region 170 with alternating positive and negative electrodes 174 and 184 therebetween. The metal wirings in the capacitive structure at this specific line level are connected to metal wirings at lower line level(s) by metal vias 176 and 186 that are located at a via level under this specific line level.

FIG. 6B shows a partial cross-sectional view of the conventional on-chip capacitor of FIG. 6A along lines I-I. Specifically, the metal wirings that form the capacitive structure shown in FIG. 6A, including the positive and negative electrodes 174 and 184, are located at an upper line level ML1 and are connected to metal wirings 178 and 188 of a lower line level ML2 by metal vias 176 and 178 of a via level VL1.

The metal wirings 174, 184, 178, and 188 used in the conventional on-chip capacitor shown by FIGS. 6A and 6B comprise standard narrow damascene copper wires of about 0.3-0.5 μm wide, which result in high capacitor resistance.

Another aspect of the present invention therefore provides an improved on-chip capacitor design. Specifically, the present invention proposes an on-chip capacitor formed by: (1) wide metal wirings located at an upper line level, (2) narrower metal wirings located at a via level (i.e., wiring-containing via level), and (3) narrower metal wirings at one or more lower line levels located under the wiring-containing via level. The IC chip may or may not actually contain metal vias that extend through the wiring-containing via level.

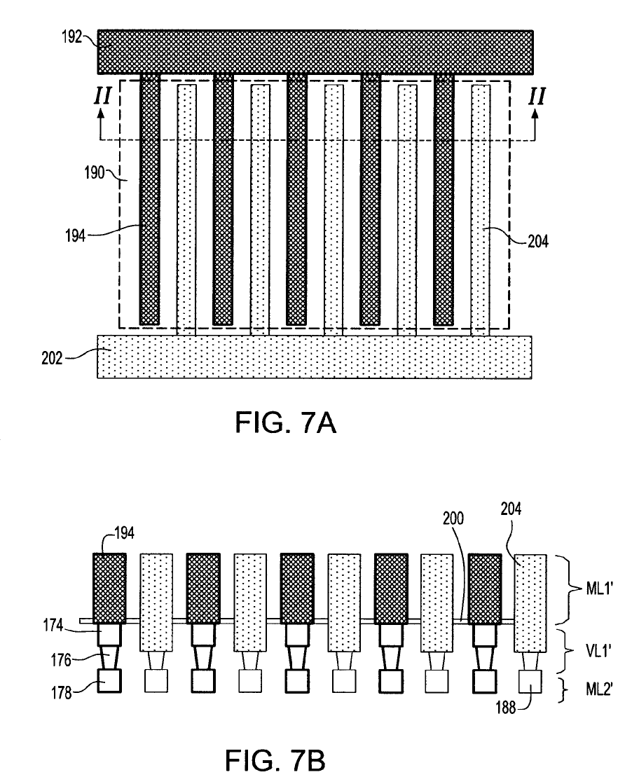

FIG. 7A shows a top view of an on-chip capacitor of the present invention, which contains metal wirings located at a specific line level and forming a positive terminal 192, a negative terminal 202, and a capacitive region 190 therebetween. Alternating positive and negative electrodes 194 and 204 extend respectively from the positive terminal 192 and the negative terminal 202 into the region 190.

FIG. 7B shows a partial cross-sectional view of the on-chip capacitor of the present invention shown in FIG. 7A along lines II-II. Specifically, The metal wirings that form the positive terminal 192, the negative terminal 202, and the positive and negative electrodes 194 and 204 are wide damascene copper wires of about 3-5 μm wide. Such wide metal wirings are formed directly over a capping layer 200 atop the narrow metal wirings 174 of the conventional on-chip capacitor shown in FIGS. 6A and 6B, and they define a new line level ML1′ (i.e., the wide line level). Consequently, the line level ML1 and the via level VL1 of the conventional on-chip capacitor as shown in FIG. 6B are merged into a new via level VL1′ under the wide line level ML1′.

In the specific embodiment shown in FIGS. 7A and 7B, the wide metal wirings 194 and 204 are formed by a single damascene process, with controlled over-etching of the wirings 204 through the capping layer 200 and partially extending into the new via level VL1′, and the new via level VL1′ does not contain actual metal vias.

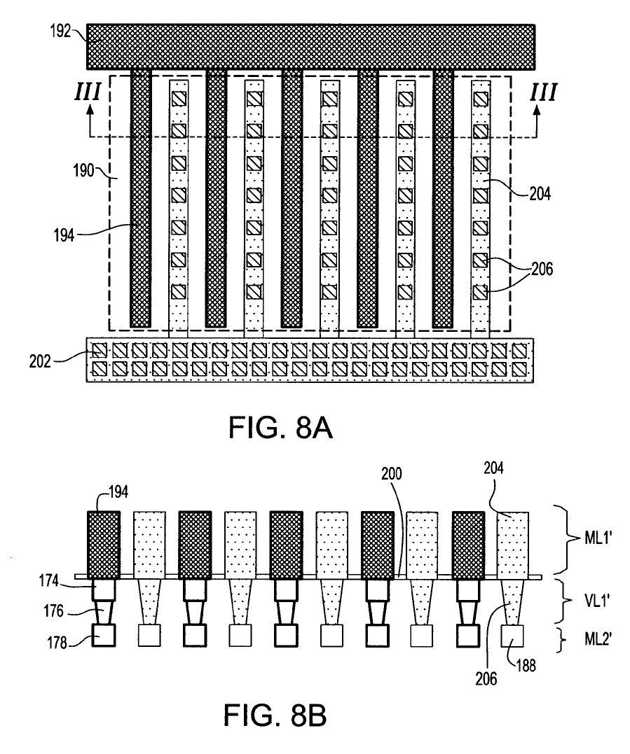

In an alternatively embodiment of the present invention, the wirings 204 are connected to lower-level wirings 188 by wide metal vias 206 located in the new via level VL1′, as shown in FIGS. 8A and 8B. The wide metal wirings 194, 204, and the wide metal vias 206 can be formed by a dual damascene process.

Note that the metal wirings as shown in FIGS. 7A-8B are preferably formed in ILD layers that comprise high k dielectric materials, such as SiCN, Ta₂O₅, Al₂O₃, HfO₂, perovskite-type oxides, such as, for example, BaTiO₃, SrTiO₃, etc. Preferably, a hybrid ILD structure that comprises a first SiCN layer of about 20-100 nm thick, a second SiO₂ layer of about 100-200 nm thick, and a third layer of about 300-500 nm thick is used for isolating the metal wirings of the present invention.

While FIGS. 2A-5 and 7A-8B illustratively demonstrates exemplary structures and processing steps, according to specific embodiments of the present invention, it is clear that a person ordinarily skilled in the art can readily modify such structures or process steps for adaptation to specific application requirements, consistent with the above descriptions. For example, while the capacitors are illustrated hereinabove as exemplary devises that can be incorporated into the via levels, it is clear that a person ordinarily skilled in the art can readily incorporate other logic circuitry components into the via levels in the IC chips of the present invention. It should therefore be recognized that the present invention is not limited to the specific embodiment illustrated hereinabove, but rather extends in utility to any other modification, variation, application, and embodiment, and accordingly all such other modifications, variations, applications, and embodiments are to be regarded as being within the spirit and scope of the invention.

What is claimed is:

1. An integrate circuit (IC) device comprising:
a first line level comprising metal wirings, electronic devices, or a combination of both;
a second line level spaced apart from the first line level, wherein the second line level comprises metal wirings, electronic devices, or a combination of both; and
a via level between the first and second line levels, wherein the via level comprises at least one metal via that extends therethrough to electrically connect the first line level with the second line level, and wherein the via level further comprises metal wirings, electronic devices, or a combination of both.

2. The IC device of claim 1, wherein the first and second line levels and the via levels are located in a hybrid dielectric structure that comprises at least two different dielectric materials.

3. The IC device of claim 1, wherein the via level comprises at least one electronic device selected from the group consisting of capacitors, diodes, resistors, transistors, inductors, and varactors.

4. The IC device of claim 1, wherein the first line level comprises at least one electronic device selected from the group consisting of capacitors, diodes, resistors, transistors, inductors, and varactors.

5. The IC device of claim 1, wherein the second line level comprises at least one electronic device selected from the group consisting of capacitors, diodes, resistors, transistors, inductors, and varactors.

6. The IC device of claim 1, wherein the first line level comprises at least one signal line, power line, or ground line, and wherein the via level comprises at least one capacitor.

7. The IC device of claim 1, wherein the first line level comprises metal wirings having a wire width ranging from about 3 μm to about 5 μm, and wherein the via level and the second line level comprise metal wirings having a wire width ranging from about 0.3 μm to about 0.5 μm.

8. The IC device of claim 7, wherein the metal wirings in the first and second line levels and the via level comprise copper wires.

9. An on-chip capacitor comprising:
a first line level comprising metal wirings having a wire width ranging from about 3 μm to about 5 μm;
a second line level spaced apart from the first line level, wherein the second line level comprises metal wirings having a wire width ranging from about 0.3 μm to about 0.5 μm; and
a via level between the first and second line levels, wherein the via level comprises metal wirings having a wire width ranging from about 0.3 μm to about 0.5 μm.

10. The on-chip capacitor of claim 9, wherein at least a portion of the metal wirings at the first line level partially extends into the via level.

11. The on-chip capacitor of claim 9, wherein the via level comprises at least one metal via that extends therethrough to electrically connect the first line level with the second line level.

12. A method for forming an IC device, comprising:
forming a lower line level in a first inter-level dielectric (ILD) layer, wherein the lower line level comprises metal wirings, electronic devices, or a combination of both;
depositing a second inter-level ILD layer over the first ILD layer;
forming metal wirings, electronic devices, or a combination of both in the second inter-level ILD layer;
depositing a third inter-level ILD layer over the second ILD layer;
forming an upper line level in the third ILD layer, wherein the upper line level comprises metal wirings, electronic devices, or a combination of both,
wherein the second ILD layer defines a via level with metal wirings, electronic devices, or a combination of both located therein, and wherein at least one metal via extends through the via level for electrically connecting the upper and lower line levels.

13. The method of claim 12, wherein the at least one metal via is formed in the via level by a single damascene process before deposition of the third inter-level ILD layer.

14. The method of claim 12, wherein the at least one metal via is formed in the via level by a dual damascene process that conjunctively forms the upper line level after deposition of the third inter-level ILD layer.

15. The method of claim 12, wherein the first, second and third ILD layers comprise the same dielectric material.

16. The method of claim 12, wherein the first, second and third ILD layers comprise at least two different dielectric materials.

17. The method of claim 12, wherein at least one electronic device selected from the group consisting of capacitors, diodes, resistors, transistors, inductors, and varactors is formed in the second ILD layer that defines the via level.

18. The method of claim 12, wherein the lower line level comprises at least one electronic device selected from the group consisting of capacitors, diodes, resistors, transistors, inductors, and varactors.

19. The method of claim 12, wherein the upper line level comprises at least one electronic device selected from the group consisting of capacitors, diodes, resistors, transistors, inductors, and varactors.

20. The method of claim 1, wherein the upper line level comprises copper wires having a wire width ranging from about 3 μm to about 5 μm, and wherein the via level and the lower line level comprise copper wires having a wire width ranging from about 0.3 μm to about 0.5 μm.
